(19) United States
(12) Patent Application Publication
(10) Pub. No.: US 2026/0040829 A1
(43) Pub. Date: Feb. 5, 2026

(54) PIEZOELECTRIC MATERIALS AND RELATED DEVICES FOR ACOUSTIC SENSOR APPLICATIONS

(71) Applicant: Robert Bosch GmbH, Stuttgart (DE)

(72) Inventors: Mordechai KORNBLUTH, Brighton, MA (US); Sanjay GOPALAN, Richardson, TX (US); Daniel PANTEL, Mundelsheim (DE)

(21) Appl. No.: 18/788,321

(22) Filed: Jul. 30, 2024

(51) Int. Cl. H10N 30/853; H10N 30/30; H10N 30/50; H10N 30/87

(52) U.S. Cl. CPC H10N 30/853; H10N 30/302; H10N 30/50; H10N 30/877

(57) ABSTRACT

Disclosed herein are a microelectromechanical system (MEMS) devices comprising a first electrode layer, an aluminum nitride based piezoelectric layer, and a second electrode layer. The aluminum nitride based piezoelectric layer comprises a piezoelectric material of formula AlₓSc_{y}Yb_{z}N, wherein x+y+z=1. Also disclosed are acoustic components comprising the piezoelectric material.

### TECHNICAL FIELD

The present disclosure relates to piezoelectric materials and devices comprising piezoelectric materials. More specifically, the disclosure relates MEMS devices, including ultrasonic acoustic components.

### BACKGROUND

Microelectromechanical systems (MEMS) are ubiquitous in modern technology, especially in electronic devices and sensors. These systems couple mechanics and electricity on a microscale, enabling new paradigms of sensing and processing. One major MEMS market is an ultrasonic transducer.

Piezoelectricity is an electro-mechanical phenomenon observed in specific asymmetric crystal structures, such as found in quartz and various ceramics. The direct piezoelectric effect is manifested when a piezoelectric material undergoes physical stress, leading to polarization and the generation of a voltage across it. Conversely, the converse piezoelectric effect occurs when the material is subjected to an electrical field, resulting in deformation-either expansion or contraction-depending on the direction of the field. Upon exposure to an electric AC signal, the piezoelectric material undergoes vibrational motion, alternately contracting and expanding. This phenomenon gives rise to the emission of (ultra-) sound waves, illustrating the practical application of piezoelectricity in the conversion of mechanical energy into electrical energy and vice versa.

Piezoelectric materials are widely employed in ultrasonic transducers owing to their exceptional electro-mechanical properties. These materials exhibit a high-frequency response, allowing for the efficient generation and detection of ultrasonic waves crucial in applications like medical imaging, cleaning processes, and distance measurement. Their compact and lightweight nature makes them suitable for diverse applications with space constraints and portability requirements. Additionally, piezoelectric transducers offer a broad frequency range, enabling adaptation to various operational needs in fields such as medical diagnostics, industrial inspections, automotive sensors and underwater communication. Renowned for their durability and stability, these materials ensure reliable performance over time. The precision and sensitivity of piezoelectric transducers make them ideal for tasks demanding accurate detection of fine details or subtle changes, as seen for example in medical imaging. Moreover, their low electrical power consumption contributes to energy efficiency in devices utilizing ultrasonic technology. Overall, the unique combination of properties in piezoelectric materials positions them as indispensable components in ultrasonic transducer applications.

Suppose we have a material with a piezoelectric tensor e and a compliance tensor s^{E} under constant electric field (inverse of a stiffness tensor c^{E} under constant electric field). In MEMS devices, typically a thin piezoelectric film is clamped to a substrate, e.g. Si substrate. For such a thin film clamped on a substrate, the key coefficients are e_{31,f} and d_{33,f}, given as follows:

$${e}_{31 , f} = \frac{{d}_{31}}{{s}_{11}^{E} + {s}_{12}^{E}} = {e}_{31} - \frac{{c}_{13}^{E}}{{c}_{33}^{E}} {e}_{33} \vert {e}_{31 , f} \vert > \vert {e}_{31} \vert$$

$${d}_{33 , f} = \frac{{e}_{33}}{{c}_{33}^{E}} = {d}_{33} - \frac{2 {s}_{13}^{E}}{{s}_{11}^{E} + {s}_{12}^{E}} {d}_{31} < {d}_{33}$$

The selection of piezoelectric materials is dependent on their applications, with each application having a figure of merit (FoM) composed of different physical properties (especially the piezoelectric coefficient and permittivity) of the piezoelectric material. The material with the highest FoM is typically the best material for the selected application.

For sensor applications (e.g. microphones), the sensitivity is described by the piezoelectric coefficient e_{31,f} and the permittivity ε_{r,33}, with the FoM being e_{31,f}/ε_{r,33} (with high e_{31,f} being advantageous for generation of high charge at given stress and a low ε_{r,33} being advantageous for yielding higher voltages with given charge) and thus AIN is preferred over lead zirconate titanate (PZT). PZT exhibits a superior piezoelectric constant e_{31, f} (piezoelectric constants vary with respect to doping ratio), which has advantages for actuator applications. The figure of merit for actuators is denoted as e_{31, f} and PZT is one of the most studied and commercially used material for applications in actuators like micro-mirrors. The key FoM for ultrasound is typically e_{31,f}²/εᵣ as for ultrasound applications an ultrasound wave has to be exited (actuation, e_{31,f}) and incoming ultrasound wave has to be detected (sensing, e_{31,f}/ε_{r,33}).

For ultrasound devices, current piezoelectric materials with high FoM require a combination of materials which require expensive and complex deposition processes. There remains a need for AIN based piezoelectric materials which have a high FoM and can be manufactured or deposited through more efficiently through economical processes.

### SUMMARY

The disclosure pertains to microelectromechanical system (MEMS) devices comprising a first electrode layer, an aluminum nitride based piezoelectric layer, and a second electrode layer. The aluminum nitride based piezoelectric layer comprises a piezoelectric material of formula AlₓSc_{y}Yb_{z}N, wherein x+y+z=1. Also disclosed herein are acoustic components comprising the piezoelectric material.

### Selected Definitions and Nomenclature

As used herein, the terms “alloy”, “alloyed”, “alloying” and “dopant”, “doped”, or “doping” can be used interchangeably to refer to the addition of elements within the piezoelectric materials, disclosed herein. The terms “alloy” or “dopant” are not intended to limit the specific atomic amount of an element that is added or incorporated into the piezoelectric materials disclosed herein.

As used herein, the term “c/a” or “c/a value” are used interchangeably and refer to a piezoelectric material's crystallographic axial distortion. As is commonly used by crystallographers, “c” represents the (conventionally third) crystallographic lattice vector length, which is approximately aligned with the polarization field, and “a” represents the crystallographic lattice vector's or vectors' length approximately transverse to the polarization field.

As used herein “wurtzite” phase crystal structure refers to a structure in which the anions have a hexagonal close packed arrangement with the cations occupying one type of tetrahedral hole.

The term “about” is used in conjunction with numeric values to include normal variations in measurements as expected by persons skilled in the art, and is understood to have the same meaning as “approximately” and to cover a typical margin of error, such as ±15%, ±10%, ±5%, ±1%, ±0.5%, or even ±0.1% of the stated value. The term “about” also encompasses amounts that differ due to different equilibrium conditions for a composition resulting from a particular initial composition. Whether or not modified by the term “about,” the claims include equivalents to the quantities.

It should be noted that, as used in this specification and the appended claims, the singular forms “a,” “an,” and “the” include plural referents unless the content clearly dictates otherwise. Thus, for example, reference to a composition containing “a compound” includes having two or more compounds that are either the same or different from each other. It should also be noted that the term “or” is generally employed in its sense including “and/or” unless the content clearly dictates otherwise. As used herein, “and/or” refers to and encompasses any and all possible combinations of one or more of the associated listed items, as well as the lack of combinations when interpreted in the alternative (“or”).

In the interest of brevity and conciseness, any ranges of values set forth in this specification contemplate all values within the range and are to be construed as support for claims reciting any sub-ranges having endpoints which are real number values within the specified range in question. By way of a hypothetical illustrative example, a disclosure in this specification of a range of from 1 to 5 shall be considered to support claims to any of the following ranges: 1-5; 1-4; 1-3; 1-2; 2-5; 2-4; 2-3; 3-5; 3-4; and 4-5.

The term “substantially” is utilized herein to represent the inherent degree of uncertainty that can be attributed to any quantitative comparison, value, measurement, or other representation. The term “substantially” is also utilized herein to represent the degree by which a quantitative representation can vary from a stated reference without resulting in a change in the basic function of the subject matter at issue.

The term “comprise,” “comprises,” and “comprising” as used herein, specify the presence of the stated features, integers, steps, operations, elements, and/or components, but do not preclude the presence or addition of one or more other features, integers, steps, operations, elements, components, and/or groups thereof.

As used herein, the transitional phrase “consisting essentially of” means that the scope of a claim is to be interpreted to encompass the specified materials or steps recited in the claim and those that do not materially affect the basic and novel characteristic(s) of the claimed invention. Thus, the term “consisting essentially of” when used in a claim of this invention is not intended to be interpreted to be equivalent to “comprising.”

As used herein, the terms “increase,” “increasing,” “increased,” “enhance,” “enhanced,” “enhancing,” and “enhancement” (and grammatical variations thereof) describe an elevation of at least about 1%, 5%, 10%, 15%, 25%, 50%, 75%, 100%, 150%, 200%, 300%, 400%, 500% or more as compared to a control.

As used herein, the terms “reduce,” “reduced,” “reducing,” “reduction,” “diminish,” and “decrease” (and grammatical variations thereof), describe, for example, a decrease of at least about 1%, 5%, 10%, 15%, 20%, 25%, 35%, 50%, 75%, 80%, 85%, 90%, 95%, 97%, 98%, 99%, or 100% as compared to a control. In particular embodiments, the reduction can result in no or essentially no (i.e., an insignificant amount, e.g., less than about 10% or even 5% or even 1%) detectable activity or amount.

The terms “preferred” and “preferably” refer to embodiments that may afford certain benefits, under certain circumstances. However, other embodiments may also be preferred, under the same or other circumstances. Furthermore, the recitation of one or more preferred embodiments does not imply that other embodiments are not useful and is not intended to exclude other embodiments from the scope of the present disclosure.

The terms “over,” “under,” “between,” and “on” as used herein refer to a relative position of one component or material with respect to other components or materials where such physical relationships are noteworthy. For example, in the context of materials, one material or material disposed over or under another may be directly in contact or may have one or more intervening materials. Moreover, one material disposed between two materials or materials may be directly in contact with the two layers or may have one or more intervening layers. In contrast, a first material or material “on” a second material or material is in direct contact with that second material/material. Similar distinctions are to be made in the context of component assemblies.

As used throughout this description, and in the claims, a list of items joined by the term “at least one of” or “one or more of” can mean any combination of the listed terms. For example, the phrase “at least one of X, Y or Z” can mean X; Y; Z; X and Y; X and Z; Y and Z; or X, Y and Z

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions.

### BRIEF DESCRIPTION OF THE DRAWINGS

FIG. 1 depicts a cross-sectional view of an embodiment of an MEMS device comprising piezoelectric materials in accordance with embodiments disclosed herein.

FIG. 2 depicts a cross-sectional view of an ultrasound transducer in accordance with embodiments disclosed herein.

FIG. 3 depicts a graphical results of e_{31,f} graphed versus permittivity ε_{zz}=ε_{r,33} for the simulated materials, as disclosed herein.

FIG. 4 is a schematic of a unit cell of a wurtzite Al—Yb—Sc—N alloy transducer in accordance with embodiments disclosed herein.

FIG. 5A shows a graphical depiction of formation energy plots for the wurtzite configuration of Al—Sc—Yb—N materials, disclosed herein.

FIG. 5B shows a graphical depiction of formation energy plots for the rocksalt configuration of Al—Sc—Yb—N materials, disclosed herein.

FIG. 5C shows a graphical depiction of formation energy plots for calculated c/a ratio for wurtzite configuration of Al—Sc—Yb—N materials, disclosed herein.

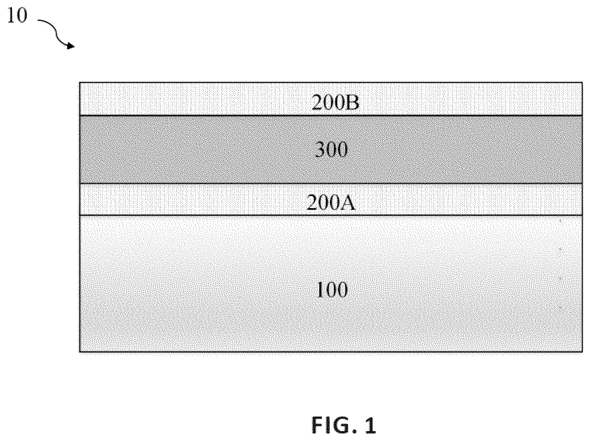

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative bases for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical application. Various combinations and modifications of the features consistent with the teachings of this disclosure, however, could be desired for particular applications or implementations.

Disclosed herein are aluminum nitride (AlN) based piezoelectric materials, and MEMS devices incorporating said piezoelectric materials. The piezoelectric materials disclosed herein are optimized for incorporation in ultrasound devices. The inventors of the present application have determined quaternary piezoelectric alloys, which have higher figure of merit (FoM), e_{31,f}²/ε_{r,33}, for ultrasound applications, when compared to currently used piezoelectric materials.

In one embodiment, a microelectromechanical system (MEMS) device 10 is disclosed, comprising a substrate 100, an aluminum nitride based piezoelectric layer 300, a first electrode layer 200A and a second electrode layer 200B. The aluminum nitride piezoelectric material in in the Al based piezoelectric layer 300 comprises AlₓSc_{y}Yb_{z}N, wherein x+y+z=1.

In one embodiment, the MEMS device 10 the aluminum nitride based piezoelectric material or layer comprises AlₓSc_{y}Yb_{z}N, wherein x+y+z=1, 0.3<x≤0.9, and |y−z|<0.2. In further embodiments, the aluminum nitride piezoelectric material is AlₓSc_{y}Yb_{z}N, wherein x+y+z=1, 0.5<x≤0.7, |y−z|<0.1, and z>y. More preferably, the aluminum nitride piezoelectric layer comprises is AlₓSc_{y}Yb_{z}N, wherein x=0.4-0.6, y=0.2-0.3, z=0.2-0.3.

In one embodiment, the MEMS device 10, incorporates a piezoelectric layer 300 which contains s a plurality of alternating layers. The layers have an Sc-rich composition and Yb-rich composition, in an alternating configuration. Such alternation is found to correlate with a high piezoelectric coefficient e_{31,f}. Each alternating layer in the plurality of alternating layers can have a thickness of about 0.3 to 30 nm.

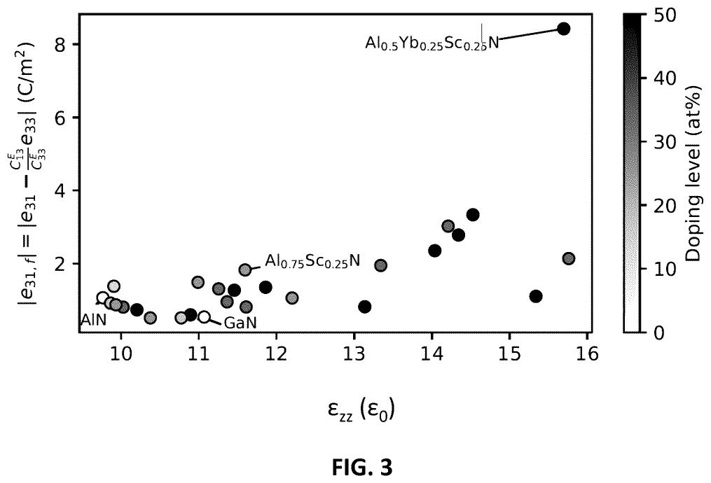

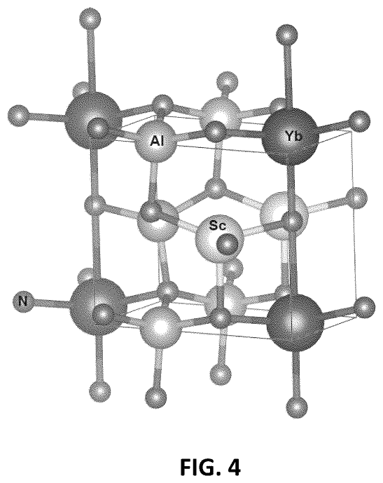

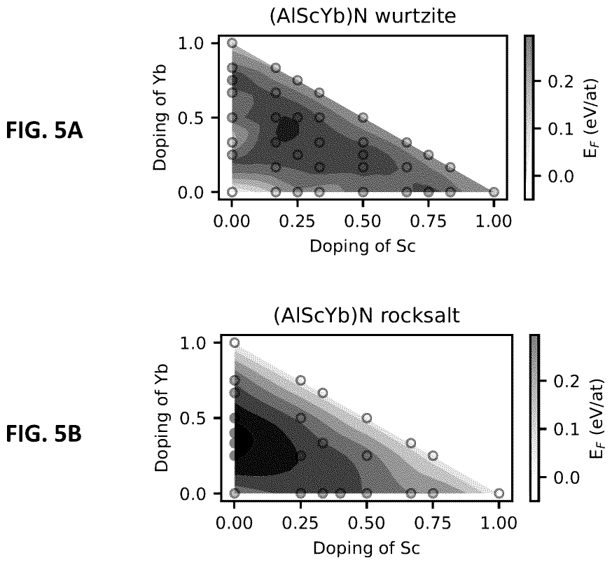

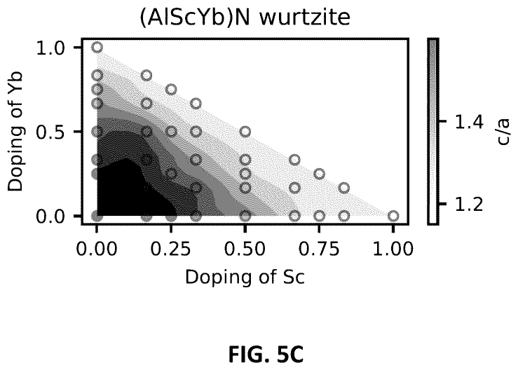

In one embodiment, piezoelectric material has a c/a value between 1.2 and 1.5. FIGS. 5A and 5B show the computed energy of formation of a given composition AlScYbN in the wurtzite and the rocksalt phase, respectively. The rocksalt phase is not piezoelectric, whereas the wurtzite phase is piezoelectric. It is known that if the alloying of AIN with Sc is more than 30-50%, there is a significant risk of rocksalt formation, which is undesirable for piezoelectric applications. This risk of rocksalt formation exists because the energy of the wurtzite and the rocksalt are close to each other, so it is difficult to preferentially grow the desired wurtzite phase. This is seen in FIGS. 5A and 5B. However, the addition of a moderate amount of Yb accomplishes two things: it stabilizes the wurtzite phase, by making the rocksalt higher energy (the darker shade on the left of FIG. 5B), and it also raises the piezoelectric e_{31,f} (shown on FIG. 3). FIG. 5C shows the computed value of c/a or the tetragonal distortion as a function of Yb and Sc doping. A lower value of c/a is correlated to a higher piezoelectric effect. In FIG. 5C we can see that both Yb and Sc are good piezoelectric additives because of their ionic and polar character.

The piezoelectric layer 300 has a thickness of about 50-2000 nm, or 100-2000 nm, or 200-2000 nm, or 300-2000 nm, or 400-2000 nm, or 500-2000 nm, or 600-2000 nm, or 700-2000 nm, or 800-2000 nm, or 900-2000 nm, or 50-1000 nm, or 100-1000 nm, or 200-1000 nm, or 300-1000 nm, or 400-1000 nm, or 500-1000 nm, or 600-1000 nm, or 700-1000 nm, or 800-1000 nm, or 900-1000 nm. In certain embodiments, the piezoelectric layer 300 has a thickness of about 50-500 nm, or 100-400 nm, or 200-300 nm, or any value or range therebetween.

The substrate layer 100 can be a ceramic material such as alumina, sapphire, glass, single-crystalline or polycrystalline aluminum nitride, gallium nitride, silicon carbide or a silicon, Si (100) or Si (111) substrate. Silicon wafers are the most common substrate for MEMS devices due to their scalability towards mass manufacturing and compatibility with various manufacturing process steps.

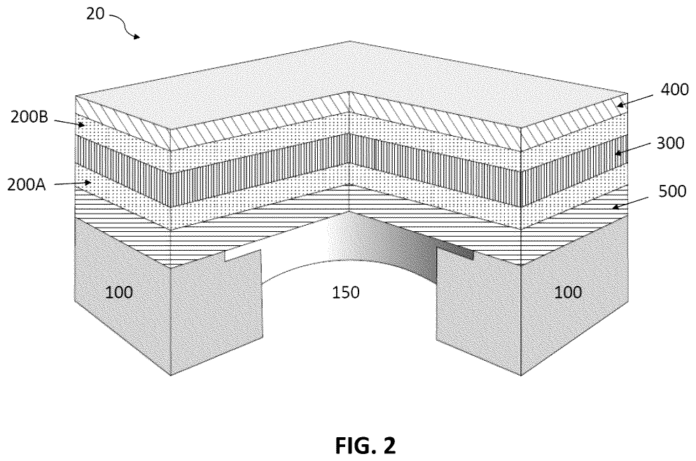

In certain embodiments, portions of the substrate layer 100 can be removed. such as the device shown in FIG. 2. This removal step and geometry will depend on the type of piezoelectric device being fabricated.

In one embodiment, an acoustic component MEMS device 20, is disclosed as shown in FIG. 2 (e.g. an acoustic sensor). The device 20 incorporates a substrate material 100, and an optional structural layer 500 deposited thereon. The substrate material 100 has an internal diaphragm 150. The device 20 further incorporates a first electrode 200A and a second electrode 200B, with a AIN based piezoelectric layer 300 sandwiched between the two electrode layers. Above the second electrode layer is a passivation layer 400. The passivation layer 400, in one embodiment, is an oxide layer, such as SiO2 or SiN. The passivation layer is optional, in certain embodiments.

The first and second electrode 200A and 200B can be composed materials that are commonly used for electrode layers in MEMS devices, including Pt, Au, Cu, Al, W, Mo, TIN, Ti, doped Si, and combinations thereof. The thickness of the electrode layers will vary per application of the MEMS device, but can be in the range of 0.05 to 0.5 μm.

The substrate layer 100 can comprise a material such Si (100) with a thickness of about 200 μm to 1.5 mm, or 380 um to 725 μm, or 675 μm or 725 μm and a diameter in the area of 100 mm-300 mm, or 150 mm-200 mm, or 300 mm, or 100 mm.

The structural layer 500 can be for example composed of SiO2 or SiN, having a thickness of about 0.3-3.0 microns.

In one embodiment, the piezoelectric layer 300, has a thickness of 50-2000 nm, can be deposited through deposition techniques including chemical vapor deposition MOCVD, molecular beam epitaxy (MBE), or sputter deposition. The piezoelectric layer 300, of device 20 shown in FIG. 2 comprises an aluminum nitride piezoelectric material such as AlₓSc_{y}Yb_{z}N, wherein x+y+z=1, 0.3<x≤0.9, and |y−z|<0.2. In further embodiments, the aluminum nitride piezoelectric material is AlₓSc_{y}Yb_{z}N, wherein x+y+z=1, 0.5<x≤0.7, |y−z|<0.1, and z>y. More preferably, the aluminum nitride piezoelectric material is AlₓSc_{y}Yb_{z}N, wherein x=0.4-0.6, y=0.2-0.3, z=0.2-0.3.

Additionally, a seed layer (not shown) can also be deposited onto electrode the first electrode 200A, also sometimes referred to as a nucleation layer or a buffer layer. In one embodiment the deposition of seed layer is an optional step. The purpose of this layer is to provide improved crystal growth and enhance crystal orientation for deposition of the functional piezoelectric material layer 300. It is to be understood that the seed layer deposition, while referenced as a single step for purposes of simplicity and brevity, can include multiple seed layers deposited in succession. In one embodiment, the seed layer comprises AIN and is deposited at a film thickness of about 10-50 nm. The seed layer is deposited on the substrate via molecular beam epitaxy, chemical vapor deposition (CVD), pulsed laser deposition, reactive sputtering, or other appropriate methods that are known to those skilled in the art. In one example, an AIN seed layer can be deposited on a Si substrate, using an Al target in a sputtering chamber, at a temperature of 350° C. Base pressure of the sputtering chamber during deposition can be about 2×10-3 mbar. Gas flows introduced during sputtering can be for example, 10 sccm of Ar and 40 sccm of N₂.

The piezoelectric properties of the proposed AlN alloys disclosed herein are computed with first principles calculations. The structural parameters are computed by density functional theory (DFT) as implemented in the Vienna ab-initio Simulation Package (VASP), using the standard set of Perdew-Burke-Ernzerhof (PBE) functional and plane augmented wave (PAW) pseudopotentials. In a case of multiple possible structures for a given composition, low-energy structures are selected with the assistance of an alloy cluster expansion. In the event multiple structures have similar energies of formation at a given composition, they are each plotted on the graph. The piezoelectric properties are computed with the density functional perturbation theory (DFPT) natively implemented in VASP. Since Cr-doped AIN is magnetic, to correctly reproduce the magnetic state, the piezoelectric tensor is calculated with the HSE hybrid functional. Table 1A and 1B below provide various piezoelectric parameter values for the piezoelectric materials disclosed herein.

TABLE 1A

| | | # | | | | |
|---|---|---|---|---|---|---|
| | | atoms | C₁₁ | | | |
| Label | Formula | in cell | (GPa) | C₃₃ | C₁₃ | C₄₄ |
| 0 | AlN | 4 | 377.246 | 357.35 | 98.558 | 112.484 |
| 6 | Al_{0.75}Sc_{0.25}N | 8 | 297.859 | 252.842 | 121.051 | 91.572 |
| 7 | Al0.75Yb0.25N | 8 | 264.956 | 253.359 | 120.677 | 80.725 |
| 9 | Al0.5Sc0.25Yb0.25N | 8 | 246.001 | 146.073 | 128.693 | 91.218 |
| 20 | Al0.5Yb0.5N | 8 | 198.145 | 173.131 | 133.441 | 86.557 |
| 63 | Al0.83Sc0.17N | 12 | 318.652 | 281.406 | 114.853 | 99.15 |
| 208 | Al0.67Sc0.17Yb0.17N | 12 | 294.276 | 200.578 | 104.618 | 87.599 |
| 213 | Al0.67Sc0.17Yb0.17N | 12 | 295.924 | 183.716 | 106.364 | 87.721 |
| 497 | Al0.67Sc0.33N | 12 | 297.343 | 213.718 | 120.005 | 94.327 |
| 499 | Al0.67Yb0.33N | 12 | 276.639 | 243.119 | 111.642 | 85.978 |

TABLE 1B

| | | εₓₓ | | | e₃₁ | | |
|---|---|---|---|---|---|---|---|
| Label | Formula | (ε₀) | ε_{yy} | ε_{zz} | (C/m²) | e₃₃ | e_{31, f} |
| 0 | AlN | 8.217 | 8.217 | 9.743 | −0.584 | 1.464 | −1.062 |
| 6 | Al_{0.75}Sc_{0.25}N | 9.773 | 9.818 | 11.584 | −0.672 | 1.881 | −1.821 |
| 7 | Al0.75Yb0.25N | 9.951 | 9.984 | 10.533 | −0.555 | 1.619 | −1.491 |
| 9 | Al0.5Sc0.25Yb0.25N | 10.943 | 10.994 | 15.725 | −0.962 | 3.348 | −8.721 |
| 20 | Al0.5Yb0.5N | 10.194 | 10.915 | 13.553 | −0.811 | 2.413 | −3.71 |
| 63 | Al0.83Sc0.17N | 9.235 | 9.281 | 11.191 | −0.672 | 1.817 | −1.604 |
| 208 | Al0.67Sc0.17Yb0.17N | 10.072 | 9.728 | 13.356 | −0.509 | 2.117 | −1.989 |
| 213 | Al0.67Sc0.17Yb0.17N | 9.946 | 9.797 | 13.579 | −0.49 | 2.299 | −2.395 |
| 497 | Al0.67Sc0.33N | 10.285 | 10.077 | 14.973 | −0.881 | 2.662 | −3.168 |
| 499 | Al0.67Yb0.33N | 10.162 | 9.928 | 15.083 | −0.923 | 2.349 | −2.411 |

The doped piezoelectric material disclosed above can be deposited by sputter deposition, molecular beam epitaxy (MBE), or chemical vapor deposition techniques such as metalorganic chemical vapor deposition (MOCVD), low pressure chemical vapor deposition (LPCVD) or atomic layer deposition (ALD). In one embodiment, the sputter deposition process comprises single target sputtering or multi-target sputtering.

In one embodiment, the deposition method is sputtering, including multi-target or single-target sputtering. In one embodiment, where multi-target sputter deposition is utilized, multiple separate targets are used, such as AlSc and YbN targets, or AlSc and AlYb targets, in the sputtering system. The frequencies and pattern of the pulses can be used to achieve the desired crystal quality and composition (e.g., by using a higher sputtering power on one target as compared to the other). The target's composition may not be identical to the final composition, due to the different mobility and sputtering yields of each element within the sputtering chamber, which yield loss or accumulation of atoms in the thin films as compared to the target. These effects can be adjusted for by increasing or lowering the corresponding atoms in the target. The piezoelectric film growth is monitored for a specific desired composition, using in-situ techniques or post-deposition analysis to ensure the desired target composition and properties. Similarly, deposition parameters (power, pressure, N₂ or Ar partial pressures, wafer temperature, DC-bias, distance target to wafer, etc.) are adjusted as needed to achieve the desired film characteristics.

Once the piezoelectric layer 300 is deposited, the second electrode layer 200B can then be deposited thereon, also by sputtering or other deposition techniques currently known and utilized in the art. An optional annealing step can further be conducted to improve crystal quality, optionally with an applied AC or DC electric field.

Also disclosed is an acoustic component, such as an acoustic sensor, comprising a substrate layer, a first electrode layer, an aluminum nitride piezoelectric layer, and a second electrode layer. The piezoelectric layer contains an aluminum nitride based piezoelectric material of formula AlₓSc_{y}Yb_{z}N, wherein x+y+z=1.

In certain embodiments, the ultrasound component can be an acoustic sensor such as a microphone, piezoelectric transducer, ultrasonic sensor, speaker, and/or acoustic emission sensor.

Additionally, the MEMS devices disclosed herein can be incorporated in an RF resonator or RF filter.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A microelectromechanical system (MEMS) device, comprising:
a first electrode layer;
an aluminum nitride based piezoelectric layer; and
a second electrode layer;
wherein the aluminum nitride based piezoelectric layer comprises AlₓSc_{y}Yb_{z}N, wherein x+y+z=1.

2. The MEMS device of claim 1, wherein the aluminum nitride based piezoelectric layer comprises AlₓSc_{y}Yb_{z}N, wherein x+y+z=1, 0.3<x≤0.9, and |y−z|<0.2.

3. The MEMS device of claim 1, wherein the aluminum nitride based piezoelectric layer comprises AlₓSc_{y}Yb_{z}N, wherein x+y+z=1, 0.5<x≤0.7, |y−z|<0.1, and z>y.

4. The MEMS device of claim 1, wherein the wherein the aluminum nitride based piezoelectric layer is AlₓSc_{y}Yb_{z}N, wherein x=0.4-0.6, y=0.2-0.3, z=0.2-0.3.

5. The MEMS device of claim 1, wherein the aluminum nitride based piezoelectric layer has a c/a value between 1.2 and 1.5.

6. The MEMS device of claim 1, wherein the aluminum nitride based piezoelectric layer comprises a plurality of alternating layers, with each alternating layer comprising a Sc-rich composition or Yb-rich composition.

7. The MEMS device of claim 6, wherein each alternating layer of the plurality of alternating layers has a thickness of about 0.3 to 30 nm.

8. The MEMS device of claim 1, wherein the first electrode and/or the second electrode comprise elements selected from the group consisting of Pt, Au, Cu, Al, W, Mo, TiN, Ti, doped Si, or a combination thereof.

9. The MEMS device of claim 1, wherein the aluminum nitride based piezoelectric layer has a thickness of about 50-2000 nm.

10. The MEMS device of claim 1, wherein the MEMS device is incorporated in an ultrasound transducer.

11. A piezoelectric material for use in an MEMS device, the piezoelectric material comprising an aluminum nitride material of formula AlₓSc_{y}Yb_{z}N, wherein x+y+z=1.

12. The piezoelectric material of claim 11, comprising AlₓSc_{y}Yb_{z}N, wherein x+y+z=1, 0.3<x≤0.9, and |y−z|<0.2.

13. The piezoelectric material of claim 11, comprising AlₓSc_{y}Yb_{z}N, wherein x+y+z=1, 0.5<x≤0.7, |y−z|<0.1, and z>y.

14. The piezoelectric material of claim 11, comprising AlₓSc_{y}Yb_{z}N, wherein x=0.4-0.6, y=0.2-0.3, z=0.2-0.3.

15. The piezoelectric material of claim 11, wherein the piezoelectric material has a c/a value between 1.2 and 1.5.

16. The piezoelectric material of claim 11, wherein the piezoelectric material comprises a plurality of alternating layers, wherein each alternating layer comprises an Sc-rich composition or Yb-rich composition.

17. An acoustic component comprising;
a substrate layer;
a first electrode layer;
an aluminum nitride based piezoelectric layer; and
a second electrode layer;
wherein the aluminum nitride based piezoelectric layer comprises AlₓSc_{y}Yb_{z}N, wherein x+y+z=1.

18. The acoustic component of claim 17, wherein the aluminum nitride based piezoelectric layer comprises AlₓSc_{y}Yb_{z}N, wherein x+y+z=1, 0.3<x≤0.9, and |y−z|<0.2.

19. The acoustic component of claim 17, wherein the aluminum nitride based piezoelectric layer comprises a plurality of alternating layers, wherein each alternating layer comprises a Sc-rich composition or Yb-rich composition.

20. The acoustic component of claim 17, wherein the aluminum nitride based piezoelectric layer comprises AlₓSc_{y}Yb_{z}N, wherein x=0.4-0.6, y=0.2-0.3, z=0.2-0.3.
